(19) United States
(12) Patent Application Publication
(10) Pub. No.: US 2026/0068607 A1
(43) Pub. Date: Mar. 5, 2026

(54) APPARATUS AND METHOD FOR MANUFACTURING DISPLAY APPARATUS

(71) Applicant: Samsung Display Co., Ltd., Yongin-si (KR)

(72) Inventors: Gwangtaek Lee, Yongin-si (KR); Taewoo Park, Yongin-si (KR); Jeongweon Seo, Yongin-si (KR); Junhee Son, Yongin-si (KR); Jeongho Hwang, Yongin-si (KR)

(21) Appl. No.: 19/316,410

(22) Filed: Sep. 2, 2025

(30) Foreign Application Priority Data
Sep. 3, 2024 (KR) 10-2024-0119558

(51) Int. Cl. H01L 21/66; H10K 59/12; H10K 71/13; H10K 71/40

(52) U.S. Cl. CPC H01L 22/24; H10K 59/1201; H10K 71/135; H10K 71/40

(57) ABSTRACT

An apparatus for manufacturing a display apparatus includes a stage on which a base substrate is seated, a discharge unit on the stage and configured to spray a first coating liquid onto the base substrate, a first sensor unit configured to detect a height of the first coating liquid applied to a first area of the base substrate, and a first temperature adjustment unit configured to adjust a temperature of the first coating liquid applied to the first area of the base substrate.

### CROSS-REFERENCE TO RELATED APPLICATION

The present application claims priority to and the benefit of Korean Patent Application No. 10-2024-0119558, filed on Sep. 3, 2024, in the Korean Intellectual Property Office, the disclosure of which is incorporated by reference herein in its entirety.

### BACKGROUND

### 1. Field

Aspects of embodiments of the present disclosure relate to an apparatus and method for manufacturing a display apparatus.

### 2. Description of the Related Art

Mobility-based electronic devices are widely used. Recently, tablet personal computers (PCs), in addition to small electronic devices, such as mobile phones, have been widely used as mobile electronic devices.

A mobile electronic device includes a display apparatus for providing visual information, such as images, to a user to support various functions. Recently, as various components for driving display apparatuses have been miniaturized, the proportion of the electronic devices occupied by display apparatuses has gradually increased, and structures that are bendable from a flat state (e.g., bendable to a certain degree or angle) have been developed.

### SUMMARY

Embodiments of the present disclosure include an apparatus for manufacturing a display apparatus that ensures a coating liquid applied to a base substrate is flat.

Aspects and features of the present disclosure are not limited to the aforementioned aspects and features.

Additional aspects and features will be set forth, in part, in the description that follows and, in part, will be apparent from the description or may be learned by practice of the described embodiments.

According to an embodiment of the present disclosure, an apparatus for manufacturing a display apparatus includes a stage configured to accommodate (or receive) a base substrate, a discharge unit on the stage and configured to spray a first coating liquid onto the base substrate, a first sensor unit configured to detect a height of the first coating liquid applied to a first area of the base substrate, and a first temperature adjustment unit configured to adjust a temperature of the first coating liquid applied to the first area of the base substrate. The first temperature adjustment unit includes a first temperature adjustment module including a 1-1 conductive unit, a 1-2 conductive unit farther from a center of the stage than the 1-1 conductive unit is, and a first element unit configured to transmit a temperature higher than room temperature to the 1-1 conductive unit and to transmit a temperature lower than room temperature to the 1-2 conductive unit, and a first position adjustment unit configured to adjust a position of the first temperature adjustment module.

The first position adjustment unit may be configured to adjust a position of the first temperature adjustment module so that a center between the 1-1 conductive unit and the 1-2 conductive unit overlaps a high point of the first coating liquid applied to the base substrate.

The first position adjustment unit may be configured to adjust a position of the first temperature adjustment module so that a center between the 1-1 conductive unit and the 1-2 conductive unit is farther from the center of the stage than a position of a high point of the first coating liquid applied to the base substrate.

The 1-2 conductive unit may be farther from the center of the stage along a first direction than the 1-1 conductive unit is, and the first position adjustment unit may be configured to linearly move the first temperature adjustment unit along the first direction.

The 1-1 conductive unit and the 1-2 conductive unit may be spaced apart from each other along the first direction.

Each of the 1-1 conductive unit and the 1-2 conductive unit may be in contact with the base substrate.

The stage may have a first stage opening overlapping the first area of the base substrate, and at least a part of the first temperature adjustment module may be accommodated in the first stage opening.

The apparatus may further include a second sensor unit configured to detect a height of the first coating liquid applied to a second area of the base substrate and a second temperature adjustment unit configured to adjust a temperature of the first coating liquid applied to the second area of the base substrate. The second temperature adjustment unit may include a second temperature adjustment module including a 2-1 conductive unit, a 2-2 conductive unit farther from the center of the stage than the 2-1 conductive unit is, and a second element unit configured to transmit a temperature higher than room temperature to the 2-1 conductive unit and to transmit a temperature lower than room temperature to the 2-2 conductive unit, and a second position adjustment unit configured to adjust a position of the second temperature adjustment module.

In a plan view, the first area and the second area may face each other with respect to the center of the stage.

The first element unit may include a Peltier element.

According to another embodiment of the present disclosure, a method of manufacturing a display apparatus includes seating a base substrate on a stage, spraying, by a discharge unit, a first coating liquid onto the base substrate, detecting, by a first sensor unit, a height of the first coating liquid applied to a first area of the base substrate, and adjusting, by a first temperature adjustment unit, a temperature of the first coating liquid applied to the first area of the base substrate. The first temperature adjustment unit includes a first temperature adjustment module including a 1-1 conductive unit, a 1-2 conductive unit farther from a center of the stage than the 1-1 conductive unit is, and a first element unit configured to transmit a temperature higher than room temperature to the 1-1 conductive unit and to transmit a temperature lower than room temperature to the 1-2 conductive unit, and a first position adjustment unit configured to adjust a position of the first temperature adjustment module.

The adjusting of the temperature of the first coating liquid may include adjusting, by the first position adjustment unit, a position of the first temperature adjustment module so that a center between the 1-1 conductive unit and the 1-2 conductive unit overlaps a high point of the first coating liquid applied to the base substrate.

The adjusting of the temperature of the first coating liquid may include adjusting, by the first position adjustment unit, a position of the first temperature adjustment module so that a center between the 1-1 conductive unit and the 1-2 conductive unit is farther from the center of the stage than a position of a high point of the first coating liquid applied to the base substrate.

The 1-2 conductive unit may be farther from the center of the stage along a first direction than the 1-1 conductive unit is, and the first position adjustment unit may be configured to linearly move the first temperature adjustment unit along the first direction.

The 1-1 conductive unit and the 1-2 conductive unit may be spaced apart from each other along the first direction.

Each of the 1-1 conductive unit and the 1-2 conductive unit may be in contact with the baser substrate.

The stage may have a first stage opening overlapping the first area of the base substrate, nd at least a part of the first temperature adjustment module may be accommodated in the first stage opening.

The method may further include detecting, by a second sensor unit, a height of the first coating liquid applied to a second area of the base substrate, and adjusting, by a second temperature adjustment unit, a temperature of the first coating liquid applied to the second area of the base substrate. The second temperature adjustment unit may include a second temperature adjustment module including a 2-1 conductive unit, a 2-2 conductive unit farther from the center of the stage than the 2-1 conductive unit is, and a second element unit configured to transmit a temperature higher than room temperature to the 2-1 conductive unit and to transmit a temperature lower than room temperature to the 2-2 conductive unit, and a second position adjustment unit configured to adjust a position of the second temperature adjustment module.

In a plan view, the first area and the second area may face each other with respect to the center of the stage.

The first element unit may include a Peltier element.

Other aspects, features, and embodiments of the present disclosure will become more apparent from the drawings, claims, and detailed description that follow.

### BRIEF DESCRIPTION OF THE DRAWINGS

The above and other aspects and features of embodiments of the present disclosure will be more apparent from the following description taken in conjunction with the accompanying drawings, in which:

FIG. 1 is a perspective view schematically illustrating an apparatus for manufacturing a display apparatus according to an embodiment;

FIG. 2 is a cross-sectional view schematically illustrating an apparatus for manufacturing a display apparatus according to an embodiment;

FIG. 3 is a flowchart describing a method of manufacturing a display apparatus according to an embodiment;

FIG. 4 is a cross-sectional view schematically illustrating an apparatus for manufacturing a display apparatus according to an embodiment;

FIG. 5 is a plan view schematically illustrating a base substrate to which a first coating liquid is to be applied according to an embodiment;

FIGS. 6 to 9 are cross-sectional views schematically illustrating an apparatus for manufacturing a display apparatus according to an embodiment;

FIG. 10 is a cross-sectional view schematically illustrating an 11^{th} coating liquid and a 12^{th} coating liquid applied to a base substrate according to an embodiment;

FIGS. 11 and 12 are perspective views schematically illustrating a part of a display apparatus according to an embodiment;

FIG. 13 is a cross-sectional view schematically illustrating a part of a display apparatus according to an embodiment; and

FIG. 14 is an equivalent circuit diagram illustrating one pixel of a display apparatus according to an embodiment.

### DETAILED DESCRIPTION

Reference will now be made, in detail, to embodiments, examples of which are illustrated in the accompanying drawings. In this regard, the described embodiments may have different forms and should not be construed as being limited to the descriptions set forth herein. Accordingly, embodiments are merely described below, by referring to the figures, to explain aspects and features of the present description. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

Because the present disclosure allows for various changes and numerous embodiments, certain embodiments will be illustrated in the drawings and described in the detailed description. Aspects and features of the present disclosure, and methods for achieving them will be clarified with reference to embodiments described below in detail with reference to the drawings. However, the present disclosure is not limited to the following embodiments and may be embodied in various forms.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Although the terms “first,” “second,” etc. may be used to describe various elements, these elements should not be limited by these terms. These terms are only used to distinguish one element from another.

As used herein, the singular forms “a” and “an” are intended to include the plural forms as well, unless the context clearly indicates otherwise.

It will be understood that the terms “comprising,” “including,” and “having” are intended to indicate the existence of the features or elements described in the specification and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the present disclosure is not limited thereto.

In the following embodiments, the x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a specific process order may be different from the described order. For example, two consecutively described processes may be performed substantially at the same time (e.g., concurrently) or may be performed in an order opposite to the described order.

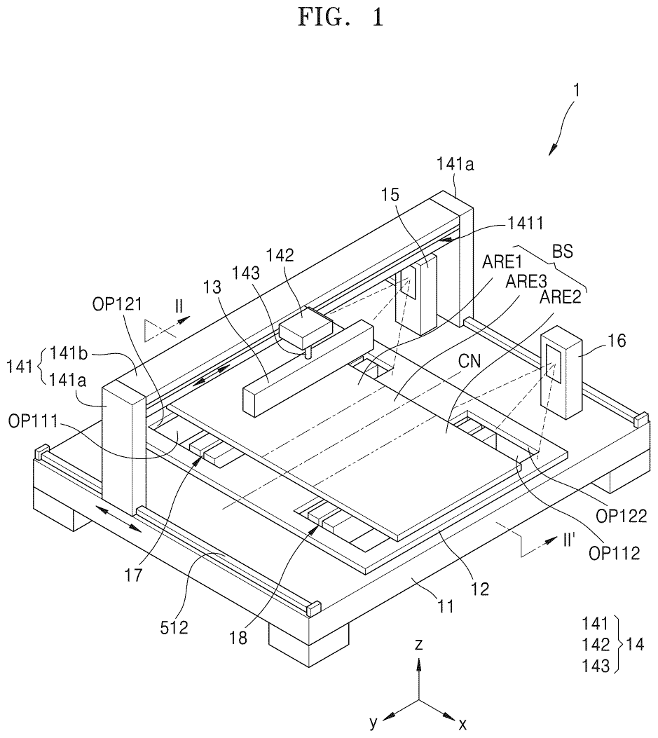

In the specification, a “plan view” refers to a two-dimensional view seen in a direction perpendicular to a base substrate BS (see, e.g., FIG. 1). That is, “A and B spaced apart from each other in a plan view” means “A and B spaced apart from each other when viewed in a direction perpendicular to the base substrate BS.”

In the specification, a “cross-sectional view” refers to a two-dimensional view cut in a direction perpendicular to the base substrate BS (see, e.g., FIG. 1). Moreover, “A and B spaced apart from each other in a plan view” means “A and B spaced apart from each other in a two-dimensional view cut in a direction perpendicular to the base substrate BS.”

The controller and/or any other relevant devices or components according to embodiments of the present disclosure described herein may be implemented utilizing any suitable hardware, firmware (e.g., an application-specific integrated circuit), software, and/or a suitable combination of software, firmware, and hardware. For example, the various components of the controller may be formed on one integrated circuit (IC) chip or on separate IC chips. Further, the various components of the controller may be implemented on a flexible printed circuit film, a tape carrier package (TCP), a printed circuit board (PCB), or formed on a same substrate as the controller. Further, the various components of the controller may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the exemplary embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

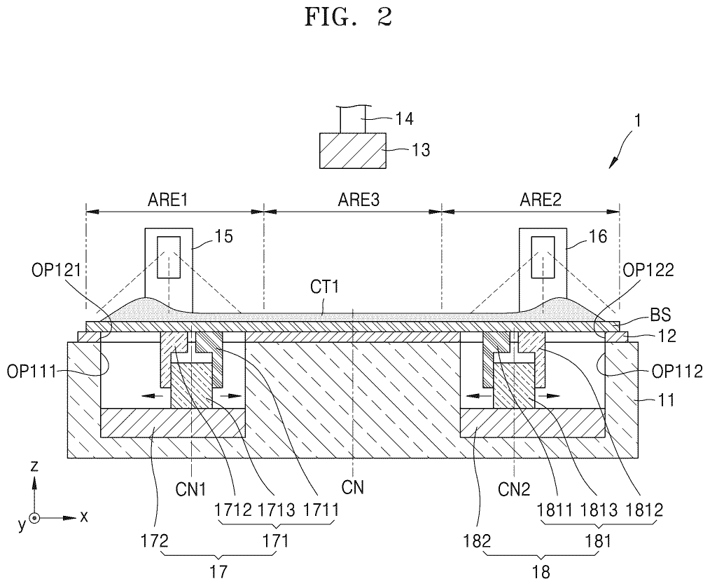

FIG. 1 is a perspective view schematically illustrating an apparatus 1 for manufacturing a display apparatus according to an embodiment. FIG. 2 is a cross-sectional view schematically illustrating the apparatus 1 for manufacturing a display apparatus.

FIG. 2 is a cross-sectional view illustrating the apparatus 1 for manufacturing a display apparatus taken along the line II-II′ in FIG. 1.

The apparatus 1 for manufacturing a display apparatus may include a support portion 11, a stage 12, a discharge unit 13, a moving unit 14, a first sensor unit 15, a second sensor unit 16, a first temperature adjustment unit 17, a second temperature adjustment unit 18, and a controller.

The support portion 11 may support the stage 12, the discharge unit 13, the moving unit 14, the first sensor unit 15, the second sensor unit 16, the first temperature adjustment unit 17, and the second temperature adjustment unit 18. The support portion 11 may have a plane defined by a first direction (e.g., an x-axis direction) and a second direction (e.g., a y-axis direction) crossing (e.g., intersecting) the first direction (e.g., the x-axis direction). The stage 12 and a guide unit 113 may be further provided on the support portion 11.

The stage 12 may be disposed on the support portion 11 and may form (or may be on) a plane defined by the first direction (e.g., the x-axis direction) and the second direction (e.g., the y-axis direction). A base substrate BS may be seated on the stage 12. The stage 12 may form a work area (e.g., a printing or deposition target) of an inject printing process.

The base substrate BS may have a thin plate shape. For example, the base substrate BS may have a quadrangular planar shape. The base substrate BS may have a plane defined by the first direction (e.g., the x-axis direction) and the second direction (e.g., the y-axis direction). However, this is only an example, and the base substrate BS may have various shapes.

The base substrate BS may have a first area ARE1, a second area ARE2, and a third area ARE3. The third area ARE3 may be disposed between the first area ARE1 and the second area ARE2. For example, the first area ARE1, the third area ARE3, and the second area ARE2 may be sequentially arranged along the first direction (e.g., the x-axis direction). The first area ARE1 and the second area ARE2 may be spaced apart from each other. The first area ARE1 and the second area ARE2 may face each other with respect to a center CN of the stage 12. The first area ARE1 and the second area ARE2 may be symmetrical to each other with respect to the center CN of the stage 12. For example, each of the first area ARE1 and the second area ARE2 may be disposed on outer portions of the base substrate BS, and the third area ARE3 may be disposed at the center of the base substrate BS.

The guide unit 113 may be disposed on the support portion 11 and may be disposed on both sides to be spaced apart from each other with the stage 12 therebetween. For example, two guide units 113 may be provided to be spaced apart from each other in the second direction (e.g., the y-axis direction). Each guide unit 113 may extend in the first direction (e.g., the x-axis direction), and an extension length of the guide unit 113 in the first direction (e.g., the x-axis direction) may be at least greater than a length of an edge of the base substrate BS in the first direction (e.g., the x-axis direction).

The guide units 113 may guide the first moving unit 141 to linearly move along the extension direction of the guide units 113. Each of the guide units 113 may include, for example, a linear motion rail.

The discharge unit 13 may be disposed over the stage 12 and may spray a first coating liquid CT1 onto the base substrate BS. The discharge unit 13 may discharge the first coating liquid CT1 along a third direction (e.g., a z-axis direction) toward the base substrate BS.

The moving unit 14 may move the discharge unit 13 relative to the stage 12. The moving unit 14 may move the discharge unit 13 in the first direction (e.g., the x-axis direction), the second direction (e.g., the y-axis direction), and the third direction (e.g., the z-axis direction). The moving unit 14 may include a first moving unit 141, a second moving unit 142, and a third moving unit 143.

The moving unit 14 may move the discharge unit 13 in the first direction (e.g., the x-axis direction) with respect to the stage 12. The first moving unit 141 may linearly reciprocate along the first direction (e.g., the x-axis direction). The first moving unit 141 may include pillar members 141a and a horizontal member 141b. Although each of the pillar members 141a and the horizontal member 141b is illustrated as having a rectangular rod shape in FIG. 1, a shape of each of the pillar members 141a and the horizontal member 141b is not limited thereto.

The pillar members 141a of the first moving unit 141 may extend in the third direction (e.g., the z-axis direction) crossing (e.g., intersecting) each of the second direction (e.g., the y-axis direction) and the first direction (e.g., the x-axis direction). For example, two pillar members 141a may be provided and may be disposed on both sides with the stage 12 therebetween. The pillar members 141a may move along the extension direction of the guide units 113, that is, the first direction (e.g., the x-axis direction). In an embodiment, the pillar members 141a may be manually linearly moved or may be automatically linearly moved by using a motor cylinder or the like. For example, the pillar members 141a may be automatically linearly moved by using a linear motion block that moves along the linear motion rail.

The horizontal member 141b of the first moving unit 141 may extend along the second direction (e.g., the y-axis direction) between the pillar members 141a. Both ends of the horizontal member 141b may be connected to upper portions of the pillar members 141a. The horizontal member 141b may include a first groove portion 1411 extending along the extension direction of the horizontal member 141b, that is, the second direction (e.g., the y-axis direction). The first groove portion 1411 may be disposed on (or formed in) a side surface of the horizontal member 141b. For example, the first groove portion 1411 may be disposed on (or formed in) one of side surfaces of the first moving unit 141 facing the first direction (e.g., the x-axis direction). The first groove portion 1411 may guide the second moving unit 142 to linearly reciprocate along the extension direction of the first groove portion 1411.

The second moving unit 142 may move the discharge unit 13 in the second direction (e.g., the y-axis direction) with respect to the stage 12. The second moving unit 142 may linearly move along the second direction (e.g., the y-axis direction). The second moving unit 142 may be movably connected to one side surface of the horizontal member 141b of the first moving unit 141. For example, the second moving unit 142 may be disposed on the side surface of the first moving unit 141 where the first groove portion 1411 is disposed. The second moving unit 142 may linearly reciprocate in the second direction (e.g., the y-axis direction) along the first groove portion 1411. In an embodiment, the second moving unit 142 may include a linear motor or the like.

The third moving unit 143 may move the discharge unit 13 in the third direction (e.g., the z-axis direction) with respect to the stage 12. In an embodiment, the third moving unit 143 may be disposed on a side surface of the second moving unit 142 and may linearly reciprocate along the third direction (e.g., the z-axis direction). For example, the third moving unit 143 may be disposed on a bottom surface of the second moving unit 142. The bottom surface of the second moving unit 142 may be a surface of the second moving unit 142 facing the stage 12. In an embodiment, the third moving unit 143 may include a pneumatic cylinder or the like. Also, the third moving unit 143 may rotate around (or about) an axial line extending in the third direction (e.g., the z-axis direction). To this end, the third moving unit 143 may include, for example, an electric motor, a pneumatic motor, or the like.

The discharge unit 13 may be disposed on a bottom surface of the third moving unit 143. The discharge unit 13 may move together when the first moving unit 141, the second moving unit 142, and the third moving unit 143 move. For example, a movement range of the discharge unit 13 may be substantially the same as the area of the support portion 11. The discharge unit 13 may also be rotated around the axial line extending in the third direction (e.g., the z-axis direction) by the third moving unit 143.

As described above, a configuration for transporting the discharge unit 13 is not limited thereto, and, for example, the discharge unit 13 may be fixed and the stage 12 may be moved. However, for convenience of explanation, the following will be described in accordance with an embodiment in which the discharge unit 13 moves in the manner described above.

The first sensor unit 15 may be disposed on the support portion 11. The first sensor unit 15 may detect a height of the first coating liquid CT1 applied to the first area ARE1 of the base substrate BS. For example, the first sensor unit 15 may detect a height of the first coating liquid CT1 disposed on an outer portion of the base substrate BS. For example, the first sensor unit 15 may include an optical sensor. The first sensor unit 15 may measure a height of the first coating liquid CT1 by measuring a time taken (or required) for light irradiated to the first coating liquid CT1 to be reflected from the first coating liquid CT1 and return to the first sensor unit 15. For example, the first sensor unit 15 may include a camera. The first sensor unit 15 may measure a height of the first coating liquid CT1 by capturing an image of the first coating liquid CT1.

The second sensor unit 16 may be disposed on the support portion 11. The second sensor unit 16 may be spaced apart from the first sensor unit 15 along the first direction (e.g., the x-axis direction). The second sensor unit 16 may detect a height of the first coating liquid CT1 applied to the second area ARE2 of the base substrate BS. For example, the second sensor unit 16 may detect a height of the first coating liquid CT1 disposed on an outer portion of the base substrate BS. For example, the second sensor unit 16 may include an optical sensor. The second sensor unit 16 may measure a height of the first coating liquid CT1 by measuring a time taken (or required) for light irradiated to the first coating liquid CT1 to be reflected from the first coating liquid CT1 and return to the second sensor unit 16. For example, the second sensor unit 16 may include a camera. The second sensor unit 16 may measure a height of the first coating liquid CT1 by capturing an image of the first coating liquid CT1.

The first temperature adjustment unit 17 may adjust a temperature of the first coating liquid CT1 applied to the first area ARE1 of the base substrate BS. The first temperature adjustment unit 17 may include a first temperature adjustment module 171 and a first position adjustment unit 172. The first temperature adjustment module 171 may include a 1-1 conductive unit 1711, a 1-2 conductive unit 1712, and a first element unit 1713.

Each of the 1-1 conductive unit 1711 and the 1-2 conductive unit 1712 may contact the base substrate BS. For example, each of the 1-1 conductive unit 1711 and the 1-2 conductive unit 1712 may contact a bottom surface of the first area ARE1 of the base substrate BS. The 1-2 conductive unit 1712 may be disposed farther from the center CN of the stage 12 than the 1-1 conductive unit 1711 is along the first direction (e.g., the x-axis direction).

The 1-1 conductive unit 1711 and the 1-2 conductive unit 1712 may be spaced apart from each other along the first direction (e.g., the x-axis direction). For example, a gap between the 1-1 conductive unit 1711 and the 1-2 conductive unit 1712 may be in a range of about 0.4 mm to about 1.0 mm. Each of the 1-1 conductive unit 1711 and the 1-2 conductive unit 1712 may include a conductive material. The center CN between the 1-1 conductive unit 1711 and the 1-2 conductive unit 1712 is referred to as a first center CN1.

The first element unit 1713 may transmit (or may emit or output) a temperature higher than room temperature to the 1-1 conductive unit 1711. The first element unit 1713 may transmit a temperature lower than room temperature to the 1-2 conductive unit 1712. For example, the first element unit 1713 may include a Peltier element.

For example, a temperature of the 1-1 conductive unit 1711 at a contact surface between the first element unit 1713 and the 1-1 conductive unit 1711 may be in a range of about 50° C. to about 70° C. For example, a temperature of the 1-2 conductive unit 1712 at a contact surface between the first element unit 1713 and the 1-2 conductive unit 1712 may be in a range of about 10° C. to about 20° C. A temperature difference between the contact surface between the first element unit 1713 and the 1-1 conductive unit 1711 and the contact surface between the first element unit 1713 and the 1-2 conductive unit 1712 may be about 65° C. For example, a temperature difference between a contact surface between the base substrate BS and the 1-1 conductive unit 1711 and a contact surface between the base substrate BS and the 1-2 conductive unit 1712 may be about 45° C.

The first position adjustment unit 172 may adjust a position of the first temperature adjustment module 171. The first position adjustment unit 172 may linearly move the first temperature adjustment unit 17 along the first direction (e.g., the x-axis direction). For example, the first position adjustment unit 172 may automatically linearly move by including a linear motion block moving along a linear motion rail.

The stage 12 may have a first stage opening OP121 overlapping (e.g., aligned with in the third direction) the first area ARE1 of the base substrate BS. The support portion 11 may have a first support opening OP111 overlapping the first area ARE1 of the base substrate BS. The first stage opening OP121 and a second support opening OP112 may overlap each other.

One side of the first position adjustment unit 172 may be fixed to the support portion 11. At least a part of the first position adjustment unit 172 may be accommodated in the first support opening OP111. At least a part of the first temperature adjustment module 171 may be accommodated in the first stage opening OP121. Top surfaces of the 1-1 conductive unit 1711 and the 1-2 conductive unit 1712 may have the same plane (e.g., may be arranged on the same plane) as a top surface of the stage 12.

However, this is only an example, a position of the first temperature adjustment unit 17 is not limited thereto. For example, the first temperature adjustment unit 17 may be disposed on the stage 12 to adjust a temperature of the first coating liquid CT1.

The second temperature adjustment unit 18 may adjust a temperature of the first coating liquid CT1 applied to the second area ARE2 of the base substrate BS. The second temperature adjustment unit 18 may include a second temperature adjustment module 181 and a second position adjustment unit 182. The second temperature adjustment module 181 may include a 2-1 conductive unit 1811, a 2-2 conductive unit 1812, and a second element unit 1813.

Each of the 2-1 conductive unit 1811 and the 2-2 conductive unit 1812 may contact the base substrate BS. For example, the 2-1 conductive unit 1811 and the 2-2 conductive unit 1812 may contact a bottom surface of the second area ARE2 of the base substrate BS. The 2-2 conductive unit 1812 may be disposed farther from the center CN of the stage 12 than the 2-1 conductive unit 1811 is along the first direction (e.g., the x-axis direction).

The 2-1 conductive unit 1811 and the 2-2 conductive unit 1812 may be spaced apart from each other along the first direction (e.g., the x-axis direction). For example, a gap between the 2-1 conductive unit 1811 and the 2-2 conductive unit 1812 may be in a range of about 0.4 mm to about 1.0 mm. Each of the 2-1 conductive unit 1811 and the 2-2 conductive unit 1812 may include a conductive material. The center CN between the 2-1 conductive unit 1811 and the 2-2 conductive unit 1812 is referred to as a second center CN2.

The second element unit 1813 may transmit a temperature higher than room temperature to the 2-1 conductive unit 1811. The second element unit 1813 may transmit a temperature lower than room temperature to the 2-2 conductive unit 1812. For example, the second element unit 1813 may include a Peltier element.

For example, a temperature of the 2-1 conductive unit 1811 at a contact surface between the second element unit 1813 and the 2-1 conductive unit 1811 may be in a range of about 50° C. to about 70° C. For example, a temperature of the 2-2 conductive unit 1812 at a contact surface between the second element unit 1813 and the 2-2 conductive unit 1812 may be in a range of about 10° C. to about 20° C. For example, a temperature difference between the contact surface between the second element unit 1813 and the 2-1 conductive unit 1811 and the contact surface between the second element unit 1813 and the 2-2 conductive unit 1812 may be about 65° C. For example, a temperature difference between a contact surface between the base substrate BS and the 2-1 conductive unit 1811 and a contact surface between the base substrate BS and the 2-2 conductive unit 1812 may be about 45° C.

The second position adjustment unit 182 may adjust a position of the second temperature adjustment module 181. The second position adjustment unit 182 may linearly move the second temperature adjustment unit 18 along the first direction (e.g., the x-axis direction). For example, the second position adjusting unit 182 may automatically linearly move by including a linear motion block moving along a linear motion rail.

The stage 12 may have a second stage opening OP122 overlapping the second area ARE2 of the base substrate BS. The support portion 11 may have a second support opening OP112 overlapping the second area ARE2 of the base substrate BS. The second stage opening OP122 and the second support opening OP112 may overlap each other.

One side of the second position adjustment unit 182 may be fixed to the support portion 11. At least a part of the second position adjustment unit 182 may be accommodated in the second support opening OP112. At least a part of the second temperature adjustment module 181 may be accommodated in the second stage opening OP122. Top surfaces of the 2-1 conductive unit 1811 and the 2-2 conductive unit 1812 may have the same plane as the top surface of the stage 12.

However, this is only an example, and a position of the second temperature adjustment unit 18 is not limited thereto. For example, the second temperature adjustment unit 18 may be disposed on the stage 12 to adjust a temperature of the first coating liquid CT1.

The controller may control the discharge unit 13, the moving unit 14, the first sensor unit 15, the second sensor unit 16, the first temperature adjustment unit 17, and the second temperature adjustment unit 18. The controller may be electrically connected to each of the discharge unit 13, the moving unit 14, the first sensor unit 15, the second sensor unit 16, the first temperature adjustment unit 17, and the second temperature adjustment unit 18. The controller may control a droplet discharge time, a droplet discharge amount, a droplet discharge position, etc. of the discharge unit 13. The controller may control a position and movement of the moving unit 14. The controller may control the first temperature adjustment unit 17 and the second temperature adjustment unit 18 based on information detected by the first sensor unit 15 and the second sensor unit 16.

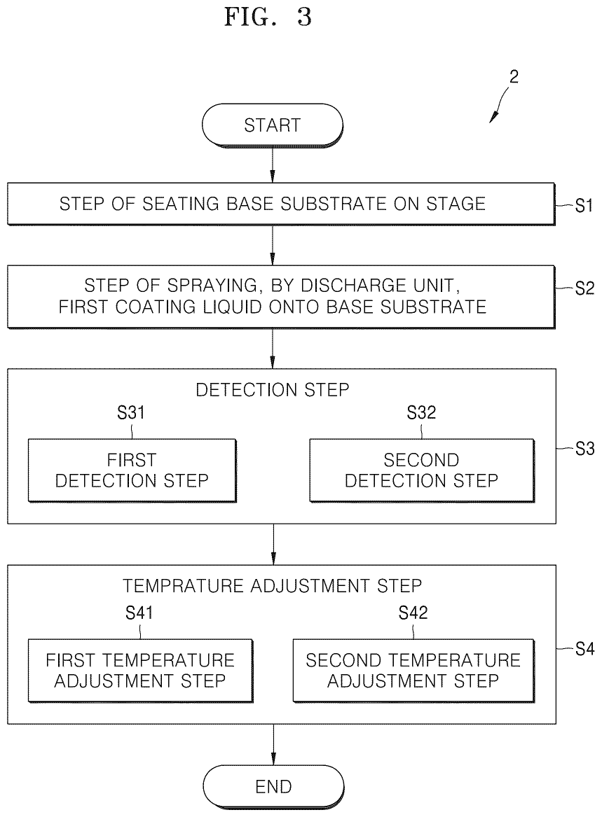

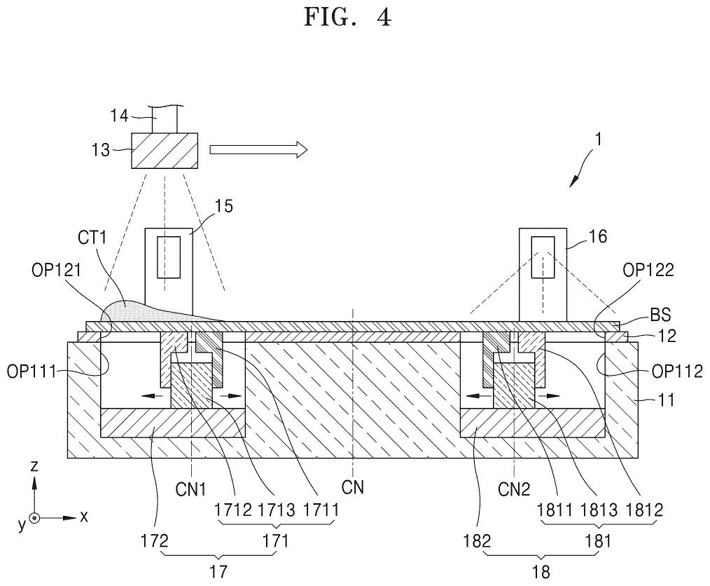

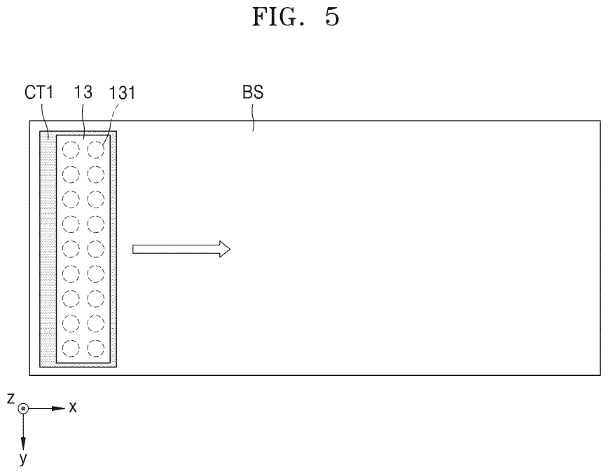

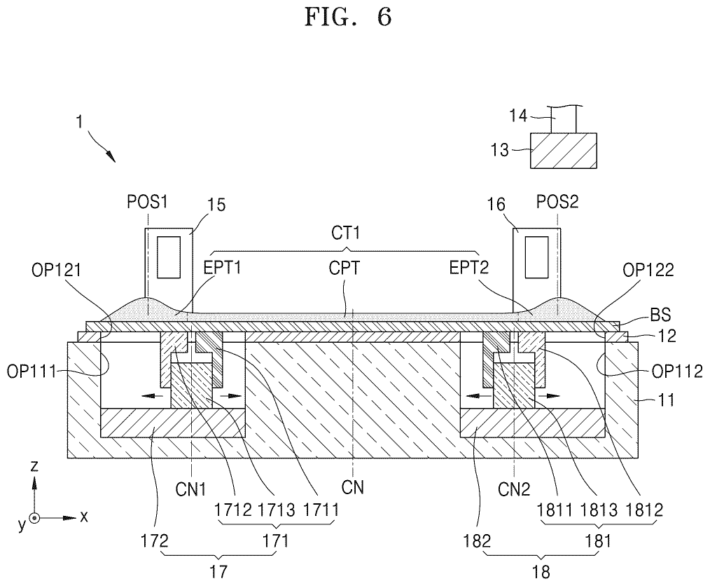

FIG. 3 is a flowchart describing a method 2 of manufacturing a display apparatus according to an embodiment. FIG. 4 is a cross-sectional view schematically illustrating the apparatus 1 for manufacturing a display apparatus according to an embodiment. FIG. 5 is a plan view schematically illustrating the base substrate BS to which the first coating liquid CT1 is to be applied according to an embodiment. FIGS. 6 to 9 are cross-sectional views schematically illustrating the apparatus 1 for manufacturing a display apparatus according to an embodiment.

In FIGS. 3 to 9, the same members as those in FIGS. 1 and 2 are denoted by the same reference numerals, and thus, a repeated description thereof will be omitted or may be only briefly provided.

Referring to FIGS. 3 to 6, the method 2 of manufacturing a display apparatus includes a step S1 of seating the base substrate BS on the stage 12 and a step S2 of spraying, by the discharge unit 13, the first coating liquid CT1 onto the base substrate BS.

The stage 12 may contact a bottom surface of the base substrate BS. An edge portion of the base substrate BS may be supported by the stage 12. Each of the first temperature adjustment module 171 and the second temperature adjustment module 181 may support the base substrate BS. Each of the 1-1 conductive unit 1711 and the 1-2 conductive unit 1712 may contact the bottom surface of the base substrate BS. Also, each of the 2-1 conductive unit 1811 and the 2-2 conductive unit 1812 may contact the bottom surface of the base substrate BS.

The discharge unit 13 may include a nozzle 131 and may discharge the first coating liquid CT1 to (e.g., on to) the base substrate BS through the nozzle 131. The nozzle 131 may be disposed on one side of the discharge unit 13, for example, a surface facing the base substrate BS. A plurality of nozzles 131 may be provided, and the plurality of nozzles 131 may be spaced apart from each other to be aligned in multiple columns and rows on the discharge unit 13.

The discharge unit 13 may move over the base substrate BS in the first direction (e.g., the x-axis direction) to spray the first coating liquid CT1 to the base substrate BS. In FIG. 5, a length of a side of the discharge unit 13 in the second direction (e.g., the y-axis direction) corresponds to a length of a side of the base substrate BS in the second direction (e.g., the y-axis direction). In such an embodiment, it may be sufficient for the discharge unit 13 to move in the first direction (e.g., the x-axis direction) to apply the first coating liquid CT1 to the entire surface (e.g., the entire upper surface) of the base substrate BS. In another embodiment, a length of a side of the discharge unit 13 in the second direction (e.g., the y-axis direction) may be less than a length of a side of the base substrate BS in the second direction (e.g., the y-axis direction), and in such an embodiment, the discharge unit 13 may move in the first direction (e.g., the x-axis direction) and the second direction (e.g., the y-axis direction) to apply the first coating liquid CT1 to one surface of the base substrate BS.

The first coating liquid CT1 applied to the base substrate BS may have a greater thickness at an outer portion of the base substrate BS than on a central portion CPT thereof. The outer portion of the first coating liquid CT1 may have a higher surface tension than the central portion CPT. Accordingly, Marangoni convection may occur from the central portion CPT to the outer portion of the first coating liquid CT1, thereby forming an edge bead.

Accordingly, the first coating liquid CT1 applied to the base substrate BS may be divided into the central portion CPT, a first edge portion EPT1, and a second edge portion EPT2. In other words, the first coating liquid CT1 may have the central portion CPT, the first edge portion EPT1, and the second edge portion EPT2. The central portion CPT may be disposed at the center of the first coating liquid CT1, and the first edge portion EPT1 and the second edge portion EPT2 may be disposed outside the first coating liquid CT1. The central portion CPT may be disposed between the first edge portion EPT1 and the second edge portion EPT2. For example, the first edge portion EPT1, the central portion CPT, and the second edge portion EPT2 may be sequentially arranged along the first direction (e.g., the x-axis direction). The first edge portion EPT1 and the second edge portion EPT2 may be spaced apart from each other. The first edge portion EPT1 and the second edge portion EPT2 may face each other with respect to the center CN of the stage 12.

In a cross-sectional view, each of the first edge portion EPT1 and the second edge portion EPT2 may have (or may be) a convex portion. In a cross-sectional view, the central portion CPT may be flat (or substantially flat) compared to the first edge portion EPT1 and the second edge portion EPT2. A portion of the first coating liquid CT1 having a top surface with a curvature that is lower than a reference (or specified) value may be defined as the central portion CPT. For example, a portion of the first coating liquid CT1 having a top surface with a curvature that is substantially zero (0) may be defined as the central portion CPT. A height of the central portion CPT of the first coating liquid CT1 may be relatively constant.

In the first coating liquid CT1, portions outside a point where a curvature of a top surface is greater than or equal to a reference (or specified) value may be defined as the first edge portion EPT1 and the second edge portion EPT2. A height of the first edge portion EPT1 of the first coating liquid CT1 may gradually increase and decrease away from the center CN of the stage 12. A height of the second edge portion EPT2 of the first coating liquid CT1 may gradually increase and decrease away from the center CN of the stage 12. A height of a high point of the first edge portion EPT1 may be greater than a height of a high point of the central portion CPT. A height of a high point of the second edge portion EPT2 may be greater than a height of a high point of the central portion CPT.

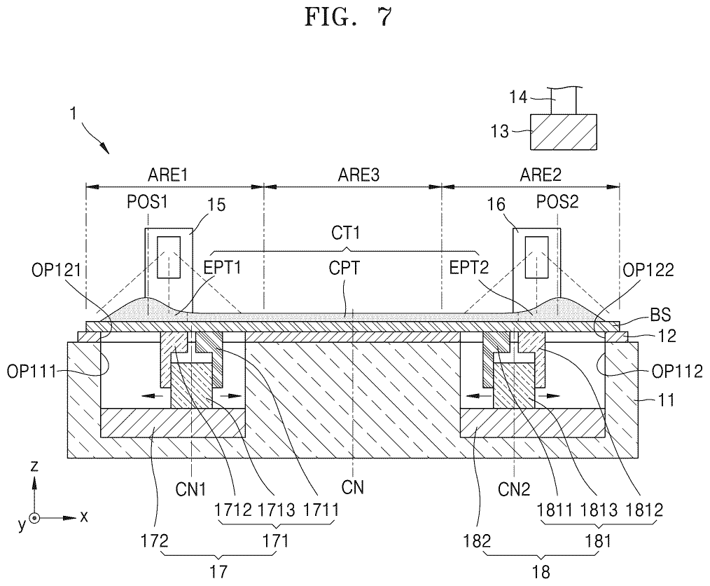

Referring to FIGS. 3 and 7, the method 2 of manufacturing a display apparatus may include a detection step S3. The detection step S3 may include a first detection step S31 and a second detection step S32. The first detection step S31 and the second detection step S32 may be concurrently (or simultaneously) performed.

The first detection step S31 may be a step in which the first sensor unit 15 detects a height of the first coating liquid CT1 applied to the first area ARE1 of the base substrate BS. The first edge portion EPT1 of the first coating liquid CT1 may overlap the first area ARE1 of the base substrate BS. The first detection step S31 may be a step in which the first sensor unit 15 detects a height of the first edge portion EPT1 of the first coating liquid CT1.

The second detection step S32 may be a step in which the second sensor unit 16 detects a height of the first coating liquid CT1 applied to the second area ARE2 of the base substrate BS. The second edge portion EPT2 of the first coating liquid CT1 may overlap the second area ARE2 of the base substrate BS. The second detection step S32 may be a step in which the second sensor unit 16 detects a height of the second edge portion EPT2 of the first coating liquid CT1.

Referring to FIGS. 3, 8, and 9, the method 2 of manufacturing a display apparatus may include a temperature adjustment step S4. The temperature adjustment step S4 may include a first temperature adjustment step S41 and a second temperature adjustment step S42. The first temperature adjustment step S41 and the second temperature adjustment step S42 may be concurrently (or simultaneously) performed.

The first temperature adjustment step S41 may be a step in which the first temperature adjustment unit 17 adjusts a temperature of the first coating liquid CT1 applied to the first area ARE1 of the base substrate BS.

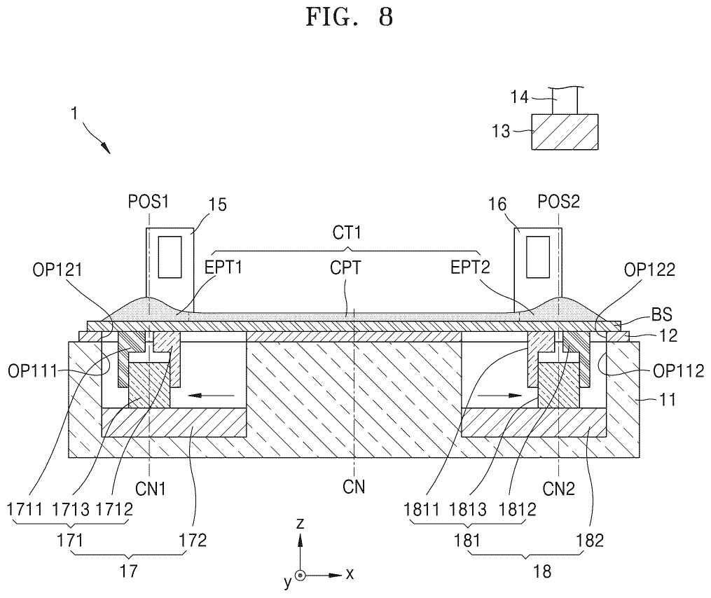

Referring to FIGS. 3 and 8, the first temperature adjustment step S41 may include a step in which the first position adjustment unit 172 adjusts a position of the first temperature adjustment module 171 so that the first center CN1 between the 1-1 conductive unit 1711 and the 1-2 conductive unit 1712 overlaps a position where a high point of the first coating liquid CT1 applied to the base substrate BS is formed. A position where a high point of the first edge portion EPT1 of the first coating liquid CT1 is defined as a first position POS1. The first temperature adjustment unit S41 may include a step in which the first position adjustment unit 172 adjusts a position of the first temperature adjustment module 171 so that the first center CN1 overlaps the first position POS1.

In another embodiment, the first temperature adjustment step S41 may include a step in which the first position adjustment unit 172 adjusts a position of the first temperature adjustment module 171 so that the first center CN1 between the 1-1 conductive unit 1711 and the 1-2 conductive unit 1712 is disposed farther from the center CN of the stage 12 than a position where a high point of the first coating liquid CT1 applied to the base substrate BS is formed. The first temperature adjustment step S41 may include a step in which the first position adjustment unit 172 adjusts a position of the first temperature adjustment module 171 so that the first center CN1 is disposed farther from the center CN of the stage 12 than the first position POS1 is.

The second temperature adjustment step S42 may be a step in which the second temperature adjustment unit 18 adjusts a temperature of the first coating liquid CT1 applied to the second area ARE2 of the base substrate BS.

The second temperature adjustment step S42 may include a step in which the second position adjustment unit 182 adjusts a position of the second temperature adjustment module 181 so that the second center CN2 between the 2-1 conductive unit 1811 and the 2-2 conductive unit 1812 overlaps a position where a high point of the first coating liquid CT1 applied to the base substrate BS is formed. A position where a high point of the second edge portion EPT2 of the first coating liquid CT1 is formed is defined as a second position POS2. The second temperature adjustment step S42 may include a step in which the second position adjustment unit 182 adjusts a position of the second temperature adjustment module 181 so that the second center CN2 overlaps the second position POS2.

In another embodiment, the second temperature adjustment step S42 may include a step in which the second position adjustment unit 182 adjusts a position of the second temperature adjustment module 181 so that the second center CN2 between the 2-1 conductive unit 1811 and the 2-2 conductive unit 1812 is disposed farther from the center CN of the stage 12 than a position where a high point of the first coating liquid CT1 applied to the base substrate BS is formed. The second temperature adjustment step S42 may include a step in which the second position adjustment unit 182 adjusts a position of the second temperature adjustment module 181 so that the second center CN2 is disposed farther from the center CN of the stage 12 than the second position POS2 is.

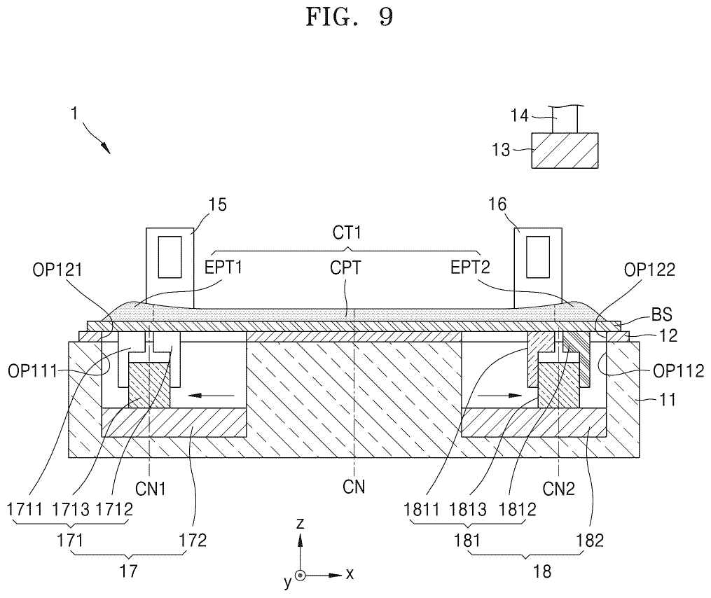

Referring to FIGS. 3 and 9, the first element unit 1713 may transmit a temperature higher than room temperature to the 1-1 conductive unit 1711 and may transmit a temperature lower than room temperature to the 1-2 conductive unit 1712. For example, heat from the 1-2 conductive unit 1712 may be transmitted to the 1-1 conductive unit 1711. Accordingly, the first edge portion EPT1 overlapping the 1-1 conductive unit 1711 may be heated, and the first edge portion EPT1 overlapping the 1-2 conductive unit 1712 may be cooled.

The second element unit 1813 may transmit a temperature higher than room temperature to the 2-1 conductive unit 1811 and may transmit a temperature lower than room temperature to the 2-2 conductive unit 1812. For example, heat from the 2-2 conductive unit 1812 may be transmitted to the 2-1 conductive unit 1811. Accordingly, the second edge portion EPT2 overlapping the 2-1 conductive unit 1811 may be heated, and the second edge portion EPT2 overlapping the 2-2 conductive unit 1812 may be cooled.

The surface tension of a portion of the first coating liquid CT1 overlapping the 1-1 conductive unit 1711 may be weakened (or reduced), and the surface tension of a portion of the first coating liquid CT1 overlapping the 1-2 conductive unit 1712 may be strengthened (or increased). The first coating liquid CT1 may flow from a position where surface tension is weaker to a position where surface tension is stronger. The first coating liquid CT1 may flow from the central portion CPT to the first edge portion EPT1.

The surface tension of a portion of the first coating liquid CT1 overlapping the 2-1 conductive unit 1811 may be weakened, and the surface tension of a portion of the first coating liquid CT1 overlapping the 2-2 conductive unit 1812 may be strengthened. The first coating liquid CT1 may flow from a position where surface tension is weak to a position where surface tension is strong. The first coating liquid CT1 may flow from the central portion CPT to the second edge portion EPT2.

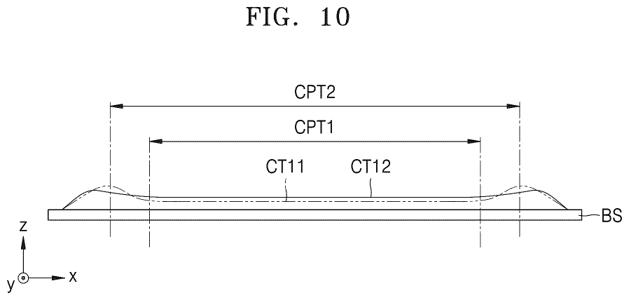

FIG. 10 is a cross-sectional view schematically illustrating an 11^{th} coating liquid CT11 and a 12^{th} coating liquid CT12 applied to the base substrate BS according to an embodiment.

Referring to FIGS. 3, 6, 9, and 10, according to the temperature adjustment step S4, a shape of the first coating liquid CT1 applied to the base substrate BS may be changed.

The first coating liquid CT1 before the temperature adjustment step S4 described with reference to FIG. 6 is referred to as the 11^{th} coating liquid CT11, and the first coating liquid CT1 after the temperature adjustment step S4 described with reference to FIG. 9 is referred to as the 12^{th} coating liquid CT12.

For example, the central portion CPT of the first coating liquid CT1 before the temperature adjustment step S4 is referred to as a first central portion CPT1 of the 11^{th} coating liquid CT11. Also, the central portion CPT of the first coating liquid CT1 after the temperature adjustment step S4 is referred to as a second central portion CPT2 of the 12^{th} coating liquid CT12.

FIG. 10 illustrates schematic shapes of the 11^{th} coating liquid CT11 and the 12^{th} coating liquid CT12. Due to the temperature adjustment step S4, a width of the second central portion CPT2 of the 12^{th} coating liquid CT12 may be increased to be greater than a width of the first central portion CPT1 of the 11^{th} coating liquid CT11. For example, due to the temperature adjustment step S4, a width of the central portion CPT of the first coating liquid CT1 that is relatively flat may increase.

The first edge portion EPT1 and the second edge portion EPT2 each having a convex portion may be removed by an additional process, and the remaining central portion CPT may be used in (or used to form) a display apparatus. For example, due to the temperature adjustment step S4, the central portion CPT of the first coating liquid CT1 may increase, thereby improving the yield of the apparatus 1 for manufacturing a display apparatus.

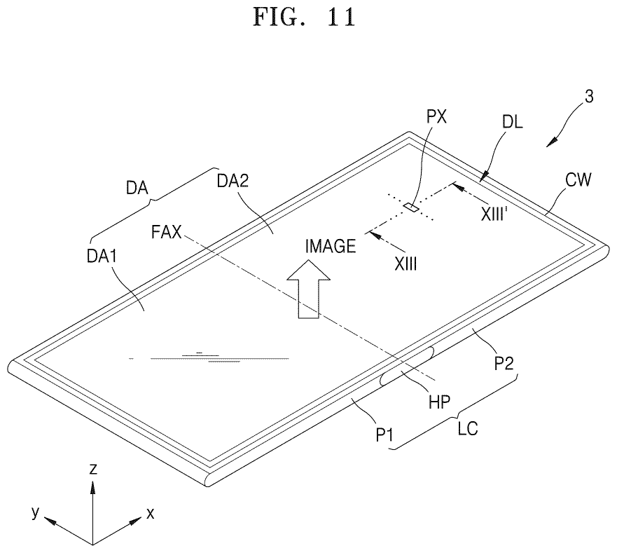

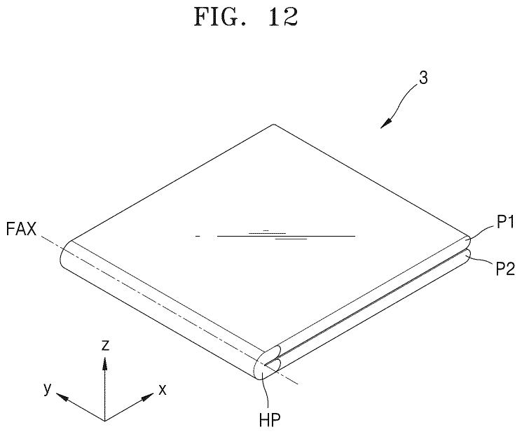

FIGS. 11 and 12 are perspective views schematically illustrating a part of a display apparatus 3 according to an embodiment. FIG. 11 illustrates the display apparatus 3 in an unfolded state. FIG. 12 illustrates the display apparatus 3 in a folded state.

Referring to FIGS. 11 and 12, the display apparatus 3 may be an electronic device including a display panel. The electronic device may be a vehicle display device including a cluster, a center information display (CID), and/or a passenger display, a wearable electronic device that may be worn on a body part of a user, a medical electronic device, a robot, an electronic device for advertising or exhibition, and/or an electronic device for education. The display apparatus 3 may include a lower cover LC, a display layer DL, and a cover window CW.

The lower cover LC may have a first portion P1 and a second portion P2 supporting the display layer DL. The lower cover LC may be folded around (or about) a folding axis FAX defined between the first portion P1 and the second portion P2. In an embodiment, the lower cover LC may have a hinge portion HP, and the hinge portion HP may be provided between the first portion P1 and the second portion P2.

The display layer DL may have a display area DA. The display layer DL may provide an image through an array of pixels PX arranged in the display area DA. Each of the pixels PX may be defined as an emission area where light is emitted by a light-emitting element electrically connected to a pixel circuit. In an embodiment, each pixel PX may emit red light, green light, or blue light. In another embodiment, each pixel PX may emit red light, green light, blue light, or white light.

The light-emitting element included in the display layer DL may include an organic light-emitting diode, an inorganic light-emitting diode, a micro light-emitting diode, and/or a quantum dot-emitting diode. Although the following embodiment is described with the light-emitting element included in the display layer DL being an organic light-emitting diode for convenience of explanation, the description below is not limited thereto and may be equally applied to other embodiments where another type of light-emitting element is used.

The display area DA may have a first display area DA1 and a second display area DA2 disposed on both sides of the folding axis FAX crossing the display area DA. The first display area DA1 and the second display area DA2 may be respectively disposed on the first portion P1 and the second portion P2 of the lower cover LC. The display layer DL may provide a first image and a second image by using light emitted from the plurality of pixels PX disposed in the first display area DA1 and the second display area DA2. In an embodiment, the first image and the second image may be portions of one image provided through the display area DA of the display layer DL. In another embodiment, the display layer DL may provide the first image and the second image, which are independent of each other.

The display layer DL may be folded around (or about) the folding axis FAX. When the display layer DL is folded, the first display area DA1 and the second display area DA2 of the display layer DL may face each other.

Although the folding axis FAX is illustrated as extending in the y-axis direction in FIGS. 11 and 12, the present disclosure is not limited thereto. In an embodiment, the folding axis FAX may extend in the x-axis direction crossing (e.g., intersecting) the y-axis direction. In another embodiment, on an x-y plane, the folding axis FAX may extend in a direction crossing (e.g., intersecting) the x-axis direction and the y-axis direction.

Also, although one folding axis FAX is illustrated in FIGS. 11 and 12, the present disclosure is not limited thereto. In an embodiment, the display layer DL may be folded several times (or at a plurality of different areas) around (or about) a plurality of folding axes FAX crossing the display area DA.

The cover window CW may be disposed on the display layer DL to cover the display layer DL. The cover window CW may be folded or bent by an external force without generating cracks (e.g., without cracking). When the display layer DL is folded around the folding axis FAX, the cover window CW may also be folded.

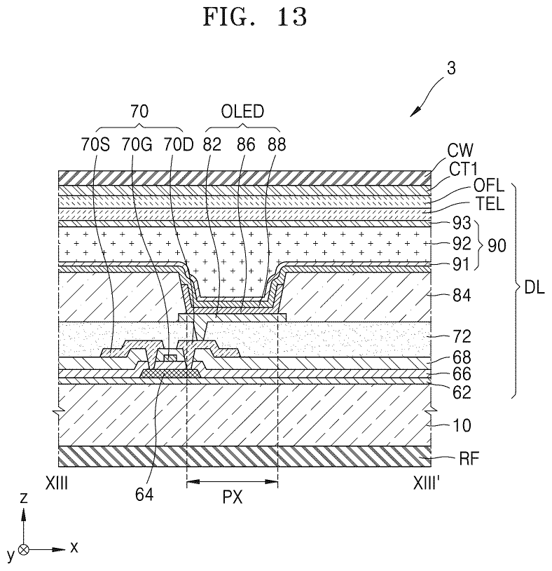

FIG. 13 is a cross-sectional view schematically illustrating a part of the display apparatus 3 according to an embodiment. FIG. 13 may be a cross-sectional view illustrating the display apparatus 3 taken along the line XIII-XIII′ in FIG. 11.

The display layer DL may be any one of, for example, an organic light-emitting display device (OLED), a liquid crystal display (LCD), and an electrophoretic display (EPD) but not limited thereto. The following embodiment will be described assuming that the display layer DL is an organic light-emitting display device.

The display layer DL may include an organic light-emitting display device including a pixel electrode 82 disposed on a first substrate 10, a pixel-defining film 84 disposed on the pixel electrode 82 and having an opening through which at least a part of the pixel electrode 82 is exposed, an intermediate layer 86 disposed on the pixel electrode 82 and including an organic emission layer, and a counter electrode 88 disposed on the intermediate layer 86.

Referring to FIG. 13, a reinforcement substrate RF may be disposed on a bottom surface of the first substrate 10. The reinforcement substrate RF is a substrate for supporting the display apparatus 3 from the first substrate 10 to the cover window CW through the display layer DL. The reinforcement substrate RF may include a reinforcement body and a reinforcement layer, described in more detail below. The reinforcement substrate RF may prevent the display layer DL from being creased in a folding area due to repeated folding.

A buffer layer 62 including an inorganic material, such as silicon oxide, silicon nitride, and/or silicon oxynitride, may be disposed on the first substrate 10. The buffer layer 62 may increase the flatness of (e.g., may planarize) a top surface of the first substrate 10 and/or may prevent or minimize penetration of impurities from the first substrate 10 or the like into an active layer 64 of a thin-film transistor 70. In some embodiments, the buffer layer 62 may be omitted.

The thin-film transistor 70 may be disposed on the first substrate 10, and the thin-film transistor 70 may be electrically connected to the pixel electrode 82. The thin-film transistor 70 may include the active layer 64 including a semiconductor material, such as amorphous silicon, polycrystalline silicon, an oxide semiconductor, or an organic semiconductor material, a gate electrode 70G insulated from the active layer 64, and a source electrode 70S and a drain electrode 70D electrically connected to the active layer 64. The gate electrode 70G may be disposed on the active layer 64, and the source electrode 70S and the drain electrode 70D are electrically communicated (e.g., are electrically connected or in electrical communication) according to a signal applied to the gate electrode 70G. Considering adhesion to an adjacent layer, surface flatness of a stacked layer, and processability, the gate electrode 70G may include at least one of, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single or multi-layer structure including the above material(s).

To ensure insulation between the active layer 64 and the gate electrode 70G, a first insulating layer 66 including an inorganic material, such as silicon oxide, silicon nitride, and/or silicon oxynitride, may be disposed between the active layer 64 and the gate electrode 70G. A second insulating layer 68 including an inorganic material, such as silicon oxide, silicon nitride, and/or silicon oxynitride, may be disposed on the gate electrode 70G, and the source electrode 70S and the drain electrode 70D may be disposed on the second insulating layer 68. The source electrode 70S and the drain electrode 70D are electrically connected to the active layer 64 through contact holes (e.g., contact openings) formed in the second insulating layer 68 and the first insulating layer 66.

A third insulating layer 72 covering the thin-film transistor 70 may be disposed on the thin-film transistor 70. The third insulating layer 72 may have a flat top surface so that the pixel electrode 82 is flat. The third insulating layer 72 may include an organic material, such as an acryl, benzocyclobutene (BCB), polyimide, or hexamethyldisiloxane (HMDSO). Although the third insulating layer 72 is illustrated as having a single-layer structure in FIG. 13, in some embodiments, the third insulating layer 72 may have a multi-layer structure.

The third insulating layer 72 includes a via hole (e.g., a through-hole or opening) through which any one of the source electrode 70S and the drain electrode 70D of the thin-film transistor 70 is exposed, and the pixel electrode 82 is electrically connected to the thin-film transistor 70 by contacting any one of the source electrode 70S and the drain electrode 70D through the via hole. In FIG. 13, the pixel electrode 82 is connected to the drain electrode 70D.

An organic light-emitting diode OLED including the pixel electrode 82, the intermediate layer 86 disposed on the pixel electrode 82 and including an organic emission layer, and the counter electrode 88 is disposed on the third insulating layer 72.

The pixel electrode 82 may be formed as a reflective electrode. When the pixel electrode 82 is formed as a reflective electrode, the pixel electrode 82 may include a reflective film formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent conductive layer disposed over/under the reflective film. The transparent conductive layer may be at least one selected from the group consisting of indium tin oxide (ITO), indium zinc oxide (IZO), zinc oxide (ZnO), indium oxide (e.g., In₂O₃), indium gallium oxide (IGO), and aluminum-doped zinc oxide (AZO). The present disclosure is not limited thereto, and the pixel electrode 82 may be formed of any of various suitable materials, and may have a single or multi-layer structure.

The pixel-defining film 84 covering an edge portion of the pixel electrode 82 may be disposed on the third insulating layer 72. The pixel-defining film 84 has an opening through which at least a part of the pixel electrode 82 is exposed and defines one pixel. The pixel-defining film 84 may be formed of an organic material, such as polyimide (PI) or hexamethyldisiloxane (HMDSO). The pixel-defining film 84 may have a single or multi-layer structure.

The intermediate layer 86 is disposed on the pixel electrode 82 exposed by the pixel-defining film 84. The intermediate layer 86 may include an organic emission layer (EML) and may further include functional layers, such as a hole injection layer (HIL), a hole transport layer (HTL), the organic emission layer (EML), an electron transport layer (ETL), and/or an electron injection layer (EIL).

A structure of the intermediate layer 86 is not limited thereto and may be any of various suitable structures. The intermediate layer 86 may include a layer that is integrally formed over a plurality of pixel electrodes 82 or may include a layer that is patterned to correspond to each of the plurality of pixel electrodes 82.

The counter electrode 88 is disposed on the intermediate layer 86. The counter electrode 88 may be integrally formed over a plurality of pixels, different from the pixel electrode 82.

The counter electrode 88 may be formed as a (semi-) transparent electrode. When the counter electrode 88 is formed as a (semi-) transparent electrode, the counter electrode 88 may include at least one material selected from among silver (Ag), aluminum (Al), magnesium (Mg), lithium (Li), calcium (Ca), copper (Cu), lithium fluoride/calcium (LiF/Ca), lithium fluoride/aluminum (LiF/Al), a magnesium-silver alloy (MgAg), and a calcium-silver alloy (CaAg), and may be formed as a thin film having a thickness in a range of several to tens of nanometers. A configuration and a material of the counter electrode 88 are not limited thereto, and various modifications may be made thereto.

A thin-film encapsulation layer 90 may be disposed on the counter electrode 88. The thin-film encapsulation layer 90 may seal the organic light-emitting diode OLED so that the organic light-emitting diode OLED is not exposed to external air and/or a foreign substance. Because the thin-film encapsulation layer 90 has a very small thickness, the thin-film encapsulation layer 90 may be a flexible or bendable encapsulation element of a flexible display apparatus that is bendable or foldable.

The thin-film encapsulation layer 90 may include a first inorganic film 91, an organic film 92, and a second inorganic film 93 sequentially disposed on the counter electrode 88. The first inorganic film 91 may include silicon oxide, silicon nitride, and/or silicon oxynitride. Because the first inorganic film 91 is formed along a lower structure, a top surface of the first inorganic film 91 is not flat as shown in FIG. 13. The organic film 92 may cover the first inorganic film 91 and may provide a flat top surface. The organic film 92 may include at least one material selected from the group consisting of polyethylene terephthalate, polyethylene naphthalate, polycarbonate, polyimide, polyethylene sulfonate, polyoxymethylene, polyarylate, and hexamethyldisiloxane. The second inorganic film 93 may cover the organic film 92 and may include silicon oxide, silicon nitride, and/or silicon oxynitride. Although the thin-film encapsulation layer 90 includes only one organic film 92 in the embodiment illustrated in FIG. 13, this is only an example, and the thin-film encapsulation layer 90 may have a structure in which multiple organic films and inorganic films are alternately stacked.

A touch electrode layer TEL including touch electrodes may be disposed on the thin-film encapsulation layer 90, and an optical functional layer OFL may be disposed on the touch electrode layer TEL. The touch electrode layer TEL may obtain coordinate information according to an external input, for example, a touch event. The optical functional layer OFL may reduce a reflectance of light (e.g., external light) incident on the display apparatus 3 and may improve color purity of light emitted from the display apparatus 3.

In an embodiment, the optical functional layer OFL may include a phase retarder and/or a polarizer. The phase retarder may be a film-type phase retarder or a liquid crystal coating-type phase retarder and may include a N/2 phase retarder and/or a N/4 phase retarder. The polarizer may also be a film-type polarizer or a liquid crystal coating-type polarizer. The film-type polarizer may include a stretchable synthetic resin film, and the liquid crystal coating-type polarizer may include liquid crystals arranged in a certain arrangement. The phase retarder and the polarizer may further include a protective film.

In an embodiment, the optical functional layer OFL may include a destructive interference structure. The destructive interference structure may include a first reflective layer and a second reflective layer disposed on different layers. First reflected light and second reflected light respectively reflected by the first reflective layer and the second reflective layer may be destructively interfered with each other, thereby reducing a reflectance of external light.

An adhesive member may be disposed between the touch electrode layer TEL and the optical functional layer OFL. The adhesive member may be a general adhesive well known in the art. For example, the adhesive member may be a pressure sensitive adhesive (PSA).

The cover window CW may be disposed on the display layer DL. The first coating liquid CT1 may be disposed between the cover window CW and the display layer DL. The cover window CW may be adhered to the display layer DL by the first coating liquid CT1. For example, the first coating liquid CT1 may be a PSA.

The cover window CW may have a high transmittance to transmit light emitted from the display layer DL. In an embodiment, a transmittance of the cover window CW may be about 85% or more, and a transmission haze may be about 2% or less, but the present disclosure is not limited thereto.

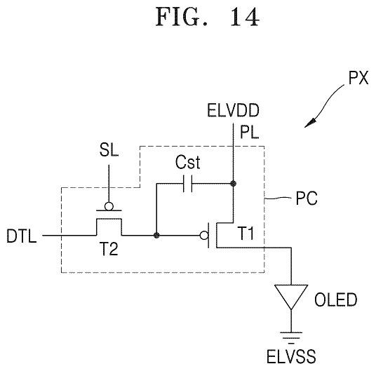

FIG. 14 is an equivalent circuit diagram illustrating one pixel PX of the display apparatus 3 according to an embodiment.

Each pixel PX may include a pixel circuit PC and a display element connected to the pixel circuit PC, for example, an organic light-emitting diode OLED. The pixel circuit PC may include a first thin-film transistor T1, a second thin-film transistor T2, and a storage capacitor Cst. Each pixel PX may emit, for example, red light, green light, blue light, or white light, through the organic light-emitting diode OLED.

The second thin-film transistor T2, that is, a switching thin-film transistor, may be connected to a scan line SL and a data line DTL and may transmit a data voltage input from the data line DTL to the first thin-film transistor T1 based on a switching voltage input from the scan line SL. The storage capacitor Cst may be connected to the second thin-film transistor T2 and a driving voltage line PL and may store a voltage corresponding to a difference between a voltage received from the second thin-film transistor T2 and a first power supply voltage ELVDD supplied to the driving voltage line PL.

The first thin-film transistor T1, that is, a driving thin-film transistor, may be connected to the driving voltage line PL and the storage capacitor Cst and may control driving current flowing from the driving voltage line PL to the organic light-emitting diode OLED in response to a value of the voltage stored in the storage capacitor Cst. The organic light-emitting diode OLED may emit light having a certain luminance due to the driving current. A counter electrode (e.g., a cathode) of the organic light-emitting diode OLED may receive a second power supply voltage ELVSS.

Although the pixel circuit PC includes two thin-film transistors and one storage capacitor in the embodiment illustrated in FIG. 14, the present disclosure is not limited thereto. The number of thin-film transistors and the number of storage capacitors may be changed in various ways according to a design of the pixel circuit PC. For example, the pixel circuit PC may include four, five, or more thin-film transistors in addition to the above two thin-film transistors described above.

While the present disclosure has been shown and described with reference to some embodiments thereof, it will be understood by one of ordinary skill in the art that various modifications and equivalent and other embodiments may be made from the present disclosure. Accordingly, the technical scope of the present disclosure is defined by the technical spirit of the appended claims and their equivalents.

According to embodiments, the yield of an apparatus for manufacturing a display apparatus may be improved.

Aspects and features of the present disclosure are not limited thereto, and other aspects and features not expressly mentioned will be clearly understood by one of ordinary skill in the art from the present disclosure and the appended claims.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims and their equivalents.

What is claimed is:

1. An apparatus for manufacturing a display apparatus, the apparatus comprising:
a stage configured to accommodate a base substrate;
a discharge unit on the stage and configured to spray a first coating liquid onto the base substrate;
a first sensor unit configured to detect a height of the first coating liquid applied to a first area of the base substrate; and
a first temperature adjustment unit configured to adjust a temperature of the first coating liquid applied to the first area of the base substrate, the first temperature adjustment unit comprising:
a first temperature adjustment module comprising a 1-1 conductive unit, a 1-2 conductive unit farther from a center of the stage than the 1-1 conductive unit is, and a first element unit configured to transmit a temperature higher than room temperature to the 1-1 conductive unit and to transmit a temperature lower than room temperature to the 1-2 conductive unit; and
a first position adjustment unit configured to adjust a position of the first temperature adjustment module.

2. The apparatus of claim 1, wherein the first position adjustment unit is configured to adjust a position of the first temperature adjustment module so that a center between the 1-1 conductive unit and the 1-2 conductive unit overlaps a high point of the first coating liquid applied to the base substrate.

3. The apparatus of claim 1, wherein the first position adjustment unit is configured to adjust a position of the first temperature adjustment module so that a center between the 1-1 conductive unit and the 1-2 conductive unit is farther from the center of the stage than a position of a high point of the first coating liquid applied to the base substrate.

4. The apparatus of claim 1, wherein the 1-2 conductive unit is farther from the center of the stage along a first direction than the 1-1 conductive unit is, and
wherein the first position adjustment unit is configured to linearly move the first temperature adjustment unit along the first direction.

5. The apparatus of claim 4, wherein the 1-1 conductive unit and the 1-2 conductive unit are spaced apart from each other along the first direction.

6. The apparatus of claim 1, wherein each of the 1-1 conductive unit and the 1-2 conductive unit is in contact with the base substrate.

7. The apparatus of claim 1, wherein the stage has a first stage opening overlapping the first area of the base substrate, and
wherein at least a part of the first temperature adjustment module is accommodated in the first stage opening.

8. The apparatus of claim 1, further comprising:
a second sensor unit configured to detect a height of the first coating liquid applied to a second area of the base substrate; and
a second temperature adjustment unit configured to adjust a temperature of the first coating liquid applied to the second area of the base substrate, the second temperature adjustment unit comprising:
a second temperature adjustment module comprising a 2-1 conductive unit, a 2-2 conductive unit farther from the center of the stage than the 2-1 conductive unit is, and a second element unit configured to transmit a temperature higher than room temperature to the 2-1 conductive unit and to transmit a temperature lower than room temperature to the 2-2 conductive unit; and
a second position adjustment unit configured to adjust a position of the second temperature adjustment module.

9. The apparatus of claim 8, wherein, in a plan view, the first area and the second area face each other with respect to the center of the stage.

10. The apparatus of claim 1, wherein the first element unit comprises a Peltier element.

11. A method of manufacturing a display apparatus, the method comprising:
seating a base substrate on a stage;
spraying, by a discharge unit, a first coating liquid onto the base substrate;
detecting, by a first sensor unit, a height of the first coating liquid applied to a first area of the base substrate; and
adjusting, by a first temperature adjustment unit, a temperature of the first coating liquid applied to the first area of the base substrate,
wherein the first temperature adjustment unit comprises:
a first temperature adjustment module comprising a 1-1 conductive unit, a 1-2 conductive unit farther from a center of the stage than the 1-1 conductive unit is, and a first element unit configured to transmit a temperature higher than room temperature to the 1-1 conductive unit and transmit a temperature lower than room temperature to the 1-2 conductive unit; and
a first position adjustment unit configured to adjust a position of the first temperature adjustment module.

12. The method of claim 11, wherein the adjusting of the temperature of the first coating liquid comprises adjusting, by the first position adjustment unit, a position of the first temperature adjustment module so that a center between the 1-1 conductive unit and the 1-2 conductive unit overlaps a high point of the first coating liquid applied to the base substrate.

13. The method of claim 11, wherein the adjusting of the temperature of the first coating liquid comprises adjusting, by the first position adjustment unit, a position of the first temperature adjustment module so that a center between the 1-1 conductive unit and the 1-2 conductive unit is farther from the center of the stage than a position of a high point of the first coating liquid applied to the base substrate.

14. The method of claim 11, wherein the 1-2 conductive unit is farther from the center of the stage along a first direction than the 1-1 conductive unit is, and
wherein the first position adjustment unit is configured to linearly move the first temperature adjustment unit along the first direction.

15. The method of claim 14, wherein the 1-1 conductive unit and the 1-2 conductive unit are spaced apart from each other along the first direction.

16. The method of claim 11, wherein each of the 1-1 conductive unit and the 1-2 conductive unit is in contact with the base substrate.

17. The method of claim 11, wherein the stage has a first stage opening overlapping the first area of the base substrate, and
wherein at least a part of the first temperature adjustment module is accommodated in the first stage opening.

18. The method of claim 11, further comprising:
detecting, by a second sensor unit, a height of the first coating liquid applied to a second area of the base substrate; and
adjusting, by a second temperature adjustment unit, a temperature of the first coating liquid applied to the second area of the base substrate, the second temperature adjustment unit comprising:
a second temperature adjustment module comprising a 2-1 conductive unit, a 2-2 conductive unit farther from the center of the stage than the 2-1 conductive unit is, and a second element unit configured to transmit a temperature higher than room temperature to the 2-1 conductive unit and transmit a temperature lower than room temperature to the 2-2 conductive unit; and
a second position adjustment unit configured to adjust a position of the second temperature adjustment module.

19. The method of claim 18, wherein, in a plan view, the first area and the second area face each other with respect to the center of the stage.

20. The method of claim 11, wherein the first element unit comprises a Peltier element.
